(19) United States
(12) Patent Application Publication
(10) Pub. No.: US 2024/0206285 A1
(43) Pub. Date: Jun. 20, 2024

(54) DISPLAY DEVICE

(71) Applicant: LG Display Co., Ltd., Seoul (KR)

(72) Inventors: Seungjin HAN, Goyang-si (KR); Dhang KWON, Paju-si (KR); HangSup CHO, Paju-si (KR)

(73) Assignee: LG Display Co., Ltd., Seoul (KR)

(21) Appl. No.: 18/502,471

(22) Filed: Nov. 6, 2023

(30) Foreign Application Priority Data
Dec. 19, 2022 (KR) 10-2022-0178420

(51) Int. Cl. H10K 59/80; H10K 59/122; H10K 59/65

(52) U.S. Cl. CPC H10K 59/8723; H10K 59/122; H10K 59/65; H10K 59/8731

(57) ABSTRACT

A display device can include a substrate including a first non-active area, an active area surrounding the first non-active area, and a second non-active area surrounding the active area, a light emitting diode disposed in the active area of the substrate, and an encapsulation layer disposed on the light emitting diode, in which the encapsulation layer includes a first inorganic encapsulation layer, an organic encapsulation layer disposed on the first inorganic encapsulation layer, and a second inorganic encapsulation layer disposed on the organic encapsulation layer. Also, a hole extends through the substrate in the first non-active area, and the organic encapsulation layer is disconnected or terminates in an area located between the active area and the hole.

### CROSS-REFERENCE TO RELATED APPLICATIONS

This application claims priority to Korean Patent Application No. 10-2022-0178420 filed in the Republic of Korea, on Dec. 19, 2022, the entirety of which is incorporated by reference into the present application.

### BACKGROUND

### Field

The present disclosure relates to a display device, and more particularly, to a display device which is capable of preventing or reducing moisture and oxygen permeation.

### Description of the Related Art

A display device can be used for various types of devices, such as TVs, monitors, tablet computers, navigations, game players, and mobile phones. For such devices, various types of display devices have been used, such as a liquid crystal display device (LCD) or an organic light emitting display device (OLED).

The display device is being developed by adding a sensor, such as a camera, a speaker, and the like. Specifically, in order to dispose a sensor, such as a camera, in the display device, a hole-in-display structure in which a hole is formed in the display device is applied.

In the display device in which a hole is formed, moisture and oxygen can additionally undesirably permeate through an area in which the hole is formed. Therefore, when the moisture or oxygen permeates through the area in which the hole is formed, the durability and reliability of the display device can be deteriorated.

### SUMMARY OF THE DISCLOSURE

An object to be achieved by the present disclosure is to provide a display device which is capable of preventing or minimizing moisture and oxygen permeation.

Another object to be achieved by the present disclosure is to provide a display device which is capable of improving a reliability of the display device.

Still another object to be achieved by the present disclosure is to provide a display device which improves a manufacturing yield of the display device by ensuring a process margin of a process of applying an organic encapsulation layer of a display device.

Objects of the present disclosure are not limited to the above-mentioned objects, and other objects, which are not mentioned above, can be clearly understood by those skilled in the art from the following descriptions.

According to an aspect of the present disclosure, the display device includes a substrate including a first non-active area, an active area which encloses the first non-active area, and a second non-active area which encloses the active area, a light emitting diode which is disposed in the active area of the substrate, and an encapsulation layer which is disposed on the substrate to cover the light emitting diode and includes a first inorganic encapsulation layer, an organic encapsulation layer disposed on the first inorganic encapsulation layer, and a second inorganic encapsulation layer disposed on the organic encapsulation layer, in which the substrate includes a hole formed in the first non-active area, and the organic encapsulation layer is disposed to be disconnected between the active area and the hole.

Other detailed matters of the example embodiments are included in the detailed description and the drawings.

According to the present disclosure, the moisture and oxygen permeation in a non-active area is suppressed and a quality of the display device is improved.

According to the present disclosure, a reliability of the display device is improved and the lifespan of the display device can be extended.

According to the present disclosure, a manufacturing yield for producing the display device is improved.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic cross-sectional view of a display device according to an embodiment of the present disclosure;

FIG. 2 is a cross-sectional view taken along line II-II′ of FIG. 1 according to an embodiment of the present disclosure;

FIG. 3 is a cross-sectional view taken along line III-III′ of FIG. 1 according to an embodiment of the present disclosure;

FIG. 4 is a cross-sectional view taken along line IV-IV′ of FIG. 1 according to an embodiment of the present disclosure; and

FIGS. 5 and 6 are cross-sectional views for explaining a manufacturing process of a display device according to an embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only.” Any references to singular can include plural unless expressly stated otherwise.

Components are interpreted to include an ordinary error range even if not expressly stated.

When the position relation between two parts is described using the terms such as “on,” “above,” “below,” and “next,” one or more parts can be positioned between the two parts unless the terms are used with the term “immediately” or “directly.”

When an element or layer is disposed “on” another element or layer, another layer or another element can be interposed directly on the other element or therebetween.

Although the terms “first,” “second,” and the like are used for describing various components, these components are not confined by these terms. These terms are merely used for distinguishing one component from the other components. Therefore, a first component to be mentioned below can be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to example embodiments of the present disclosure will be described in detail with reference to accompanying drawings. All components of each display device according to all embodiments of the present disclosure are operatively coupled and configured.

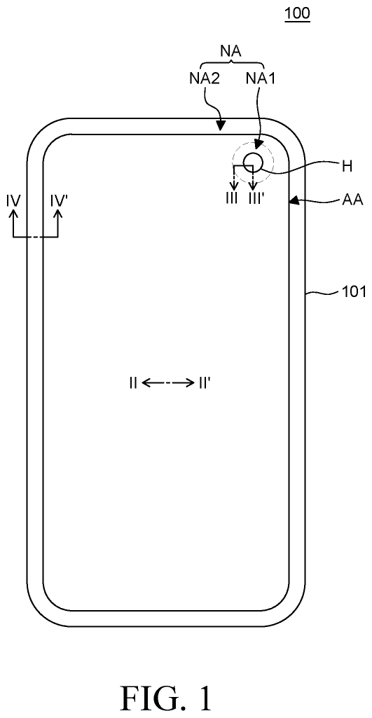

FIG. 1 is a schematic cross-sectional view of a display device according to an example embodiment of the present disclosure.

Referring to FIG. 1, a display device 100 includes a substrate 101 which can be flexible.

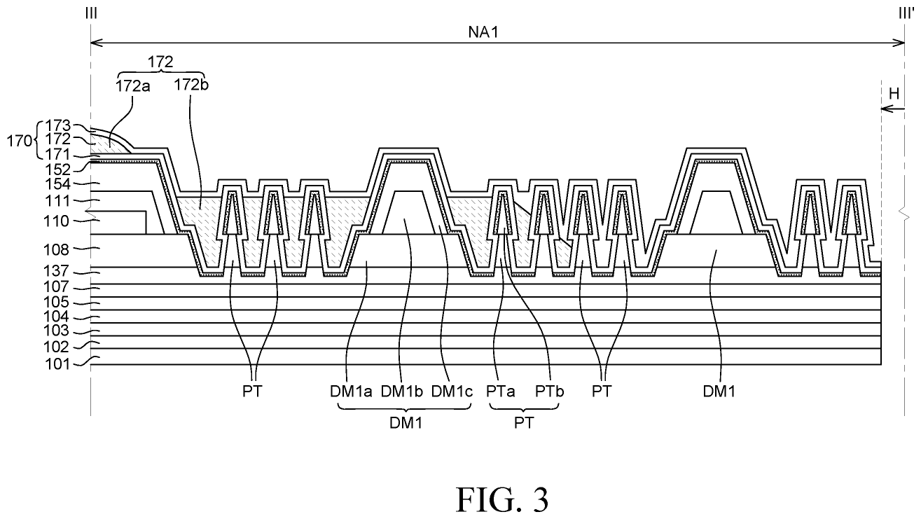

The substrate 101 can include a hole H. The hole H can be a hole which passes all the way through the substrate 101 and other components on the substrate 101. Further, the hole H can be formed to correspond to a camera or a photo sensor. Thus, a hole-in-display structure (also termed as an HID structure) is formed in the display device 100. The hole H will be described below with reference to FIG. 3.

The substrate 101 includes an active area AA and a non-active area NA.

The active area AA is an area where images are displayed. In the active area AA, a plurality of sub pixels for displaying images and a pixel circuit for driving the plurality of sub pixels can be disposed. Each of the plurality of sub pixels is an individual unit which emits light and a light emitting diode can be disposed in each of the plurality of sub pixels. The plurality of sub pixels includes a red sub pixel, a green sub pixel, a blue sub pixel, and a white sub pixel, but is not limited thereto. The pixel circuit can include various transistors, storage capacitors, and wiring lines for driving the plurality of sub pixels. For example, the pixel circuit can be configured by various components, such as a driving transistor, a switching transistor, a sensing transistor, a storage capacitor, a gate line, and a data line, but is not limited thereto.

The non-active area NA is an area where no image is displayed. The non-active area NA includes a first non-active area NA1 and a second non-active area NA2. The hole H is formed in the first non-active area NA1 and thus the HID structure is surround by the first non-active area NA1.

In the first non-active area NA1, various wiring lines, such as a data line, a high potential power line, and a gate line, can be disposed. In the first non-active area NA1 in the vicinity of the hole H, various wiring lines detour the hole H to be electrically connected to the light emitting diode and the pixel circuit which are disposed vertically and horizontally with respect to the hole H. As illustrated in FIG. 1, one hole H can be provided, but it is not limited thereto, and a plurality of holes can be disposed in various positions. For example, one or two holes are disposed in the first non-active area NA1 so that the camera is disposed in a first hole and various sensors, such as a distance sensing sensor or a face recognition sensor, can be disposed in a second hole.

The second non-active area NA2 can be disposed to enclose the active area AA. In the second non-active area NA2, various wiring lines and driving circuits for driving the plurality of sub pixels disposed in the active area AA are disposed. For example, in the second non-active area NA2, a driving circuit, such as a gate driving circuit, various wiring lines, or pads can be disposed, but is not limited thereto.

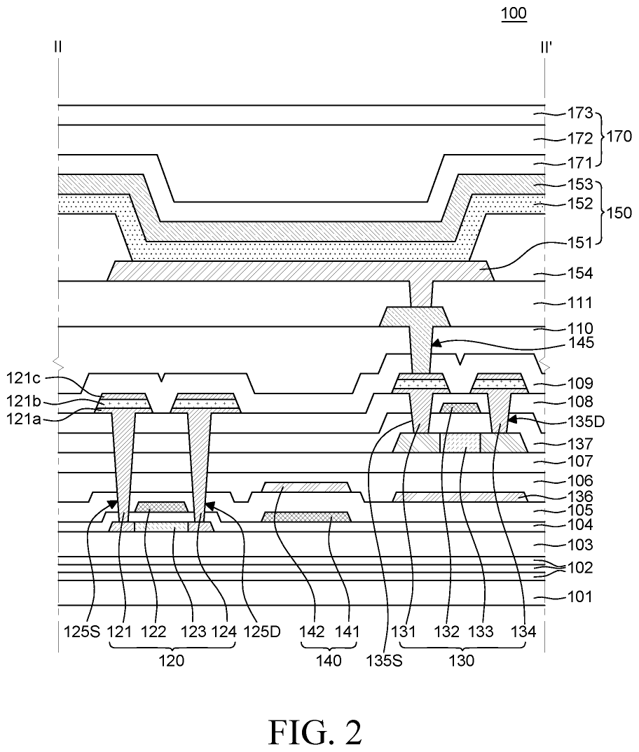

FIG. 2 is a cross-sectional view taken along line II-II′ of FIG. 1. FIG. 2 is a cross-sectional view of one sub pixel of a display device according to an example embodiment of the present disclosure.

Referring to FIG. 2, the display device 100 can include a substrate 101, a first transistor 120 (also termed as a switching transistor), a second transistor 130 (also termed as a driving transistor), a light emitting diode 150, and an encapsulation layer 170.

The substrate 101 is a support member for supporting other components of the display device 100 and can be configured by an insulating material. For example, the substrate 101 can be formed of glass, resin, or the like. Further, the substrate 101 can be configured to include plastics such as polymer or polyimide (PI) or can be formed of a material having a flexibility.

A multi-buffer layer 102 is disposed on the substrate 101. The multi-buffer layer 102 can reduce permeation of moisture or impurities through the substrate 101. The multi-buffer layer 102 can be formed by alternately laminating a-Si (amorphous silicon), silicon nitride (SiNx), and silicon oxide (SiOx) at least one time.

A lower buffer layer 103 is disposed on the multi-buffer layer 102. The lower buffer layer 103 can protect the first transistor 120 and the second transistor 130 from impurities such as alkali ions leaked from the substrate 101. Furthermore, the lower buffer layer 103 can enhance an adhesiveness between layers formed above the lower buffer layer and the substrate 101. The lower buffer layer 103 can be configured by a single layer or a double layer of a-Si, silicon oxide SiOx or silicon nitride SiNx, but is not limited thereto. In the meantime, the lower buffer layer 103 can be omitted depending on the design.

The first transistor 120 is disposed on the lower buffer layer 103. The first transistor 120 can include a first source electrode 121, a first gate electrode 122, a first semiconductor layer 123, and a first drain electrode 124.

The first semiconductor layer 123 can be formed of polycrystalline semiconductor and the first semiconductor layer 123 can include a channel region, a source region, and a drain region. The first semiconductor layer 123 can be formed of polycrystalline semiconductor having a mobility higher than that of amorphous semiconductor and oxide semiconductor, but is not limited thereto.

A lower gate insulating layer 104 is disposed on the first semiconductor layer 123. The lower gate insulating layer 104 is disposed on the first semiconductor layer 123 to insulate the first semiconductor layer 123 and the first gate electrode 122 from each other. The lower gate insulating layer 104 can be formed of an insulating inorganic material such as silicon oxide SiOx or silicon nitride SiNx or an insulating organic material.

The first gate electrode 122 is disposed on the lower gate insulating layer 104. The first gate electrode 122 can be disposed to overlap with the first semiconductor layer 123. The first gate electrode 122 can be formed of a single layer or multiple layers formed of any one of molybdenum (Mo), aluminum (Al), chrome (Cr), gold (Au), titanium (Ti), nickel (Ni), neodymium (Nd), and copper (Cu) or an alloy thereof, but is not limited thereto.

A first lower interlayer insulating layer 105 is disposed on the first gate electrode 122. The first lower interlayer insulating layer 105 can be formed of an insulating material. In the meantime, the first lower interlayer insulating layer 105 can be formed of an inorganic layer having a content of hydrogen particles higher than that of an upper interlayer insulating layer 108 which will be described below. For example, the first lower interlayer insulating layer 105 can be formed of silicon nitride SiNx which is formed by a deposition process using NH3 gas. Accordingly, hydrogen particles included in the first lower interlayer insulating layer 105 are diffused into the polycrystalline semiconductor layer during a hydrogenation process so that pores in the polycrystalline semiconductor layer are filled with hydrogen. Accordingly, the polycrystalline semiconductor layer stabilizes to suppress the deterioration of the characteristic of the first transistor 120.

A light shielding layer 136 is disposed on the first lower interlayer insulating layer 105. The light shielding layer 136 can be configured by a conductive material, such as copper (Cu), aluminum (Al), molybdenum (Mo), nickel (Ni), titanium (Ti), chrome (Cr), or an alloy thereof, but it is not limited thereto.

A second lower interlayer insulating layer 106 is disposed on the light shielding layer 136. The second lower interlayer insulating layer 106 can be formed of an inorganic layer having a content of hydrogen particles higher than that of the upper interlayer insulating layer 108, like the first lower interlayer insulating layer 105. For example, the second lower interlayer insulating layer 106 can be formed of silicon nitride SiNx which is formed by a deposition process using NH3 gas, but is not limited thereto.

An upper buffer layer 107 is disposed on the second lower interlayer insulating layer 106. The upper buffer layer 107 can be formed of a-Si, silicon nitride (SiNx), or silicon oxide (SiOx), but is not limited thereto.

The second transistor 130 is disposed on the upper buffer layer 107. The second transistor 130 can include a second source electrode 131, a second gate electrode 132, a second semiconductor layer 133, and a second drain electrode 134.

The second semiconductor layer 133 of the second transistor 130 can be disposed on the upper buffer layer 107 to overlap the light shielding layer 136.

The second semiconductor layer 133 of the second transistor 130 can be disposed after an activation and hydrogenation process of the first semiconductor layer 123 of the first transistor 120. Therefore, the second semiconductor layer 133 is not exposed to the high temperature atmosphere of the activation and hydrogenation process of the first semiconductor layer 123 so that the damage to the second semiconductor layer 133 is suppressed to improve the reliability. At this time, the second semiconductor layer 133 can be formed of oxide semiconductor or amorphous semiconductor and the second semiconductor layer 133 can include a channel region, a source region, and a drain region. The second semiconductor layer 133 can be formed of oxide semiconductor or amorphous semiconductor having a mobility lower than that of polycrystalline semiconductor, but is not limited thereto.

As such, the first semiconductor layer 123 and the second semiconductor layer 133 can be formed of different materials with different mobility to meet different requirements for achieving respectively functions of switching or driving. For example, the first transistor 120 can have a high response rate and the second transistor 130 can have a low power consumption. Also, the pixel in which the first transistor 120 and the second transistor 130 are included can have a better display performance.

Furthermore, the thickness of the first semiconductor layer 123 is different from than the thickness the second semiconductor layer 133. As shown in FIG. 2, the second semiconductor layer 133 is thicker than the first semiconductor layer 123. Thus, the first semiconductor layer 123 can have a higher resistivity than the second semiconductor layer 133 to achieve a matching design between the two transistors in one sub pixel.

An upper gate insulating layer 137 is disposed on the second semiconductor layer 133. The upper gate insulating layer 137 can insulate the second gate electrode 132 and the second semiconductor layer 133 from each other. The upper gate insulating layer 137 can be formed of an insulating inorganic material such as silicon oxide SiOx or silicon nitride SiNx or an insulating organic material.

The second gate electrode 132 is disposed on the upper gate insulating layer 137. The second gate electrode 132 can be formed of the same material as the first gate electrode 122. For example, the second gate electrode 132 can be formed of a single layer or multiple layers formed of any one of molybdenum (Mo), aluminum (Al), chrome (Cr), gold (Au), titanium (Ti), nickel (Ni), neodymium (Nd), and copper (Cu) or an alloy thereof, but is not limited thereto.

The upper interlayer insulating layer 108 is disposed on the second gate electrode 132. The upper interlayer insulating layer 108 is formed of an inorganic layer having a content of hydrogen particles lower than that of the first lower interlayer insulating layer 105 and the second lower interlayer insulating layer 106. For example, the upper interlayer insulating layer 108 can be formed of silicon oxide SiOx.

After disposing the upper interlayer insulating layer 108, a first source contact hole 125S and a first drain contact hole 125D can be formed continuously in the upper interlayer insulating layer 108, the upper gate insulating layer 137, the upper buffer layer 107, the second lower interlayer insulating layer 106, the first lower interlayer insulating layer 105 and the lower gate insulating layer 104 to correspond to the source region and the drain region of the first transistor 120. Further, a second source contact hole 135S and a second drain contact hole 135D can be formed in the upper interlayer insulating layer 108 and the upper gate insulating layer 137 to correspond to the source region and the drain region of the second transistor 130.

Each of the first source electrode 121, the first drain electrode 124, the second source electrode 131 and the second drain electrode 134 can be a single layer or multiple layers formed of any one of molybdenum (Mo), aluminum (Al), chrome (Cr), gold (Au), titanium (Ti), nickel (Ni), neodymium (Nd), and copper (Cu) or an alloy thereof, but are not limited thereto. Each of the first source electrode 121, the first drain electrode 124, the second source electrode 131 and the second drain electrode 134 can be formed of a triple layered structure. For example, the first source electrode 121 can be configured by a first layer 121a, a second layer 121b, and a third layer 121c and the other source and drain electrodes can have the same structure.

The first source electrode 121 and the first drain electrode 124 of the first transistor 120 and the second source electrode 131 and the second drain electrode 134 of the second transistor 130 can be simultaneously formed. By doing this, the number of times of a process of forming source and drain electrodes of the first transistor 120 and the second transistor 130 can be reduced.

In the meantime, a storage capacitor 140 can be disposed between the first transistor 120 and the second transistor 130. As illustrated in FIG. 2, the storage capacitor 140 can include a storage lower electrode 141 and a storage upper electrode 142 which are disposed with the first lower interlayer insulating layer 105 therebetween.

The storage lower electrode 141 is disposed on the lower gate insulating layer 104. The storage lower electrode 141 can be formed of the same material on the same layer as the first gate electrode 122. For example, the storage lower electrode 141 can be formed of a single layer or multiple layers formed of any one of molybdenum (Mo), aluminum (Al), chrome (Cr), gold (Au), titanium (Ti), nickel (Ni), neodymium (Nd), and copper (Cu) or an alloy thereof, but is not limited thereto.

The storage upper electrode 142 is disposed on the first lower interlayer insulating layer 105. The storage upper electrode 142 is formed of the same material on the same layer as the light shielding layer 136. For example, the storage upper electrode 142 can be configured by a conductive material, such as copper (Cu), aluminum (Al), molybdenum (Mo), nickel (Ni), titanium (Ti), chrome (Cr), or an alloy thereof, but it is not limited thereto.

In the meantime, the storage upper electrode 142 is spaced apart from the light shielding layer 136 as illustrated in FIG. 2, but can be connected to and be integrated with the light shielding layer.

A passivation layer 109 is disposed on the first source electrode 121, the first drain electrode 124, the second source electrode 131, and the second drain electrode 134. The passivation layer 109 can be configured by an inorganic insulating material such as SiNx or SiOx.

A first planarization layer 110 and a second planarization layer 111 are disposed on the passivation layer 109. The first planarization layer 110 and the second planarization layer 111 are insulating layers which planarize an upper portion of the substrate 101. The first planarization layer 110 and the second planarization layer 111 are formed of an organic material, and for example, can be configured by a single layer or a double layer of polyimide or photo acryl, but are not limited thereto.

The first planarization layer 110 can include a contact hole which electrically connects the second transistor 130 and a connection electrode 145. Specifically, the first planarization layer 110 can include a contact hole which exposes any one of the second source electrode 131 or the second drain electrode 134 of the second transistor 130.

The second planarization layer 111 can include a contact hole which electrically connects the connection electrode 145 and an anode electrode 151 of the light emitting diode 150.

The connection electrode 145 is disposed between the first planarization layer 110 and the second planarization layer 111. The connection electrode 145 connects the second source electrode 131 of the second transistor 130 and the anode electrode 151 of the light emitting diode 150. Even though in FIG. 2, it is illustrated that the connection electrode 145 is connected to the second source electrode 131, the connection electrode 145 can be connected to the second drain electrode 134. The connection electrode 145 can be configured by a conductive material, such as copper (Cu), aluminum (Al), molybdenum (Mo), nickel (Ni), titanium (Ti), chrome (Cr), or an alloy thereof, but is not limited thereto.

The light emitting diode 150 is disposed on the first transistor 120 and the second transistor 130. The light emitting diode 150 includes the anode electrode 151, an emission stack 152, and a cathode electrode 153.

In the meantime, the display device 100 can be implemented by a top emission type or a bottom emission type. In the top emission type, a reflective layer which reflects light emitted from the emission stack 152 toward the cathode electrode 153 can be disposed below the anode electrode 151. For example, the reflective layer can include a material having an excellent reflectivity, such as aluminum (Al), or silver (Ag), but is not limited thereto. In contrast, in the bottom emission type, the anode electrode 151 can be formed only by a transparent conductive material. Hereinafter, the description will be made under the assumption that the display device 100 according to the example embodiment of the present disclosure is a top emission type.

The anode electrode 151 is disposed on the second planarization layer 111. The anode electrode 151 can correspond to each of the plurality of sub pixels. That is, the anode electrode 151 can be patterned to correspond to each of the plurality of sub pixels one by one. The anode electrode 151 can be electrically connected to the connection electrode 145 and the second source electrode 131 of the second transistor 130 through contact holes formed in the second planarization layer 111 and the first planarization layer 110.

The anode electrode 151 can be formed of a conductive material having a high work function to supply holes to the emission stack 152. For example, the anode electrode 151 can be formed with a transparent conductive material such as indium tin oxide (ITO) and indium zinc oxide (IZO), but is not limited thereto.

A bank 154 is disposed on the anode electrode 151 and the second planarization layer 111 on the substrate 101. The bank 154 can be formed on the second planarization layer 111 to cover an edge of the anode electrode 151.

The bank 154 is an insulating layer disposed between the plurality of sub pixels to divide the plurality of sub pixels for defining an emission area and a non-emission area of the light emitting diode disposed in each of the plurality of sub pixel. The bank 154 can be an organic insulating material. For example, the bank 154 can be formed of polyimide, acryl, or benzocyclobutene (BCB)-based resin, but it is not limited thereto.

The emission stack 152 is disposed on the anode electrode 151 and the bank 154. The emission stack 152 can be formed over the entire surface of the substrate 101. That is, the emission stack 152 can be a common layer which is commonly formed in the plurality of sub pixels. The emission stack 152 can be an organic layer which emits light having a specific color. The emission stack 152 can include various layers, such as a hole transport layer, a hole injection layer, a hole blocking layer, an electron injection layer, an electron blocking layer, and an electron transport layer. In a tandem structure in which a plurality of light emitting layers overlap, a charge generation layer can be further disposed between the light emitting layers.

The light emitting layer can be individually disposed in every sub pixel to emit different color light from each sub pixel. For example, a red light emitting layer, a green light emitting layer, and a blue light emitting layer can be individually disposed in every sub pixel. However, a common light emitting layer is formed to emit white light without distinguishing colors for every pixel and a color filter which distinguishes colors can be separately provided.

The cathode electrode 153 is disposed on the emission stack 152. The cathode electrode 153 can be formed over the entire surface of the substrate 101 as one layer. That is, the cathode electrode 153 can be a common layer which is commonly formed in the plurality of sub pixels. The cathode electrode 153 supplies electrons to the emission stack 152 so that the cathode electrode can be formed of a conductive material having a low work function. For example, the cathode electrode 153 can be formed with a transparent conductive material such as indium tin oxide (ITO) or indium zinc oxide (IZO), or a metal alloy such as MgAg or an ytterbium (Yb) alloy and can further include a metal doped layer, but is not limited thereto.

The encapsulation layer 170 is disposed on the light emitting diode 150. The encapsulation layer 170 protects the light emitting diode 150 from moisture permeating from the outside of the display device 100. The encapsulation unit 170 includes a first inorganic encapsulation layer 171, an organic encapsulation layer 172, and a second inorganic encapsulation layer 173.

The first inorganic encapsulation layer 171 is disposed on the cathode electrode 153 to suppress the permeation of the moisture or oxygen. The first inorganic encapsulation layer 171 can be formed of an inorganic material, such as silicon oxide (SiOx), silicon nitride (SiNx), silicon oxy nitride (SiNxOy), or aluminum oxide (AlyOz), but is not limited thereto.

The organic encapsulation layer 172 is disposed on the first inorganic encapsulation layer 171 to planarize the surface. Further, the organic encapsulation layer 172 can cover or protect from foreign materials or particles which can be generated during a manufacturing process. The organic encapsulation layer 172 can be formed of an organic material, such as silicon oxy carbon (SiOxCz), acryl or epoxy-based resin, but is not limited thereto.

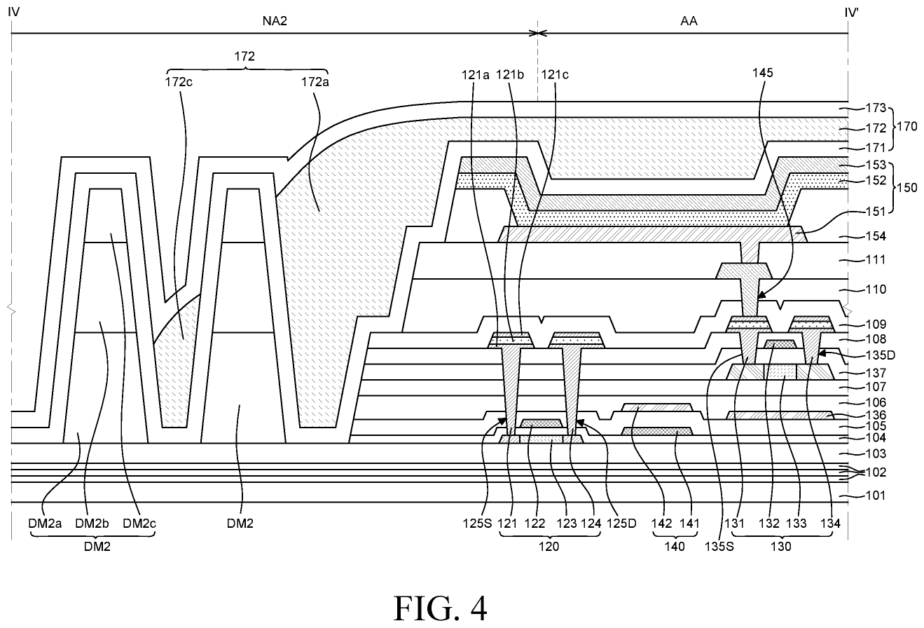

The organic encapsulation layer 172 includes a first organic encapsulation layer disposed in the active area AA, a second organic encapsulation layer disposed between the first organic encapsulation layer and the hole H to be spaced apart from the first organic encapsulation layer, and a third organic encapsulation layer disposed in the second non-active area NA2 to be spaced apart from the first organic encapsulation layer, so that the organic encapsulation layer 172 is disconnected or cut between the active area and the hole H and in the second non-active area NA2. In other words, the organic encapsulation layer 172 can terminate before reaching the hole H. The organic encapsulation layer 172 will be described below in detail with reference to FIGS. 3 and 4.

The second inorganic encapsulation layer 173 is disposed on the organic encapsulation layer 172 and can suppress the permeation of the moisture or oxygen, like the first inorganic encapsulation layer 171. At this time, the second inorganic encapsulation layer 173 and the first inorganic encapsulation layer 171 can be formed to seal the organic encapsulation layer 172. Accordingly, the moisture or oxygen permeating the light emitting diode 150 can be effectively reduced by the second inorganic encapsulation layer 173. The second inorganic encapsulation layer 173 can be formed of an inorganic material, such as silicon oxide (SiOx), silicon nitride (SiNx), silicon oxy nitride (SiNxOy), or aluminum oxide (AlyOz), but is not limited thereto.

Hereinafter, a first non-active area NA1 of a display device 100 according to an example embodiment of the present disclosure will be described with reference to FIG. 3.

FIG. 3 is a cross-sectional view taken along line III-III′ of FIG. 1 according to an embodiment of the present disclosure. FIG. 3 is a schematic cross-sectional view of a first non-active area NA1 with a hole H.

Referring to FIG. 3, a hole H is disposed in the first non-active area NA1. In a position corresponding to the hole H, a camera can be disposed below the substrate 101, but is not limited thereto and a photo sensor can be disposed in the hole H. The hole H allows light from above to easily reach the camera or the photo sensor.

Referring to FIG. 3, a plurality of first dams DM1, a plurality of patterns PT, and an encapsulation layer 170 are disposed in the first non-active area NA1.

The plurality of first dams DM1 can be disposed between the hole H and the active area AA. Although it is shown that there are two first dams DM1 in FIG. 3, the number of first dams is not limited thereto. For example, three or more first dams can be disposed between the hole H and the active area AA.

The plurality of first dams DM1 are disposed to enclose or encircle the hole H. For example, the plurality of first dams DM1 can fully surround the hole H in a plan view. Each of the plurality of first dams DM1 can be disposed in a closed curve shape enclosing the outer periphery of the hole H. The first dam DM1 can suppress overflowing of the organic encapsulation layer 172 into the hole H.

The first dam DM1 includes a first sub dam DM1a, a second sub dam DM1b, and a third sub dam DM1c. The first sub dam DM1a can be formed of an inorganic layer. The first sub dam DM1a is formed of the same material as the upper interlayer insulating layer 108 and the upper gate insulating layer 137. The second sub dam DM1b and the third sub dam DM1c can be formed of an organic layer. The second sub dam DM1b can be formed of the same material as the first planarization layer 110 and/or the second planarization layer 111. The third sub dam DM1c can be formed of the same material as the bank 154, simultaneously. However, a material of the insulating layer of the first dam DM1 and the number of layers are not limited thereto.

The plurality of patterns PT can be disposed to be spaced apart from each other in various areas between one of the plurality of first dams DM1 which is closest to the active area AA and the bank 154 in the first non-active area NA1 (or the first planarization layer 110 and the second planarization layer 111), between the plurality of first dams DM1, and between one of the plurality of first dams DM1 which is closest to the hole H and the hole H. Each of the plurality of patterns PT can be formed in a closed curve shape enclosing the outer periphery of the hole H. For example, the plurality of patterns PT can fully surround the hole H in a plan view. Although it is shown in FIG. 3 that there are three patterns PT between the one of the plurality of first dams DM1 which is closest to the active area AA and the bank 154 in the first non-active area NA1, four patterns PT between the plurality of first dams DM1, and two patterns PT between one of the plurality of first dams DM1 which is closest to the hole H and the hole H, the numbers of patterns are not limited thereto. For example, more patterns or fewer patterns than those shown in FIG. 3 can be disposed in an area.

Each of the plurality of patterns PT includes a first sub pattern PTa and a second sub pattern PTb. The first sub pattern PTa can be formed of an inorganic layer. The first sub pattern PTa is formed of the same material as the upper interlayer insulating layer 108 and the upper gate insulating layer 137. The second sub pattern PTb can be formed of an organic layer. The second sub pattern PTb can be formed of the same material as the first planarization layer 110 and the second planarization layer 111, but a material which configures the plurality of patterns PT and the number of layers are not limited thereto.

The plurality of patterns PT can suppress moisture from permeating into the active area AA through the emission stack 152. That is, the emission stack 152, which is vulnerable to the moisture permeation, can have a disconnection structure by the plurality of patterns PT. For example, the emission stack 152 can be repeatedly cut or disconnected by the plurality of patterns PT before reaching the hole H. Specifically, a cross-sectional shape of the first sub pattern PTa and the second sub pattern PTb of the plurality of patterns PT has a tapered trapezoidal shape and a top surface of the first sub pattern PTa has a smaller width than that of a bottom surface of the second sub pattern PTb.

In the meantime, the emission stack 152 and the cathode electrode 153 of the light emitting diode 150 are common layers to be disposed to extend from the active area AA into the first non-active area NA1. Accordingly, the emission stack 152 disposed above and between the plurality of patterns PT is not continuous, but can be disconnected or cut due to the plurality of patterns PT. Thus, the emission stack disposed above and between the plurality of first dams DM1 is disconnected too.

Accordingly, even though the moisture permeates through the emission stack 152 from the hole H, the disconnected structure of the emission stack 152 can suppress the permeated moisture from moving to the active area AA. For example, the emission stack 152 and the organic encapsulation layer 172 may be prone to wicking moisture from an area by the hole H to the active area AA. Thus, the plurality of first dams DM1 can cut the organic encapsulation layer 172 and cause the organic encapsulation layer 172 to terminate before reaching the hole H. Similarly, both of the plurality of first dams DM1 and the plurality of patterns PT cut the emission stack 152 and cause the emission stack 152 to terminate before reaching the hole H. In this way, any risk of wicking moisture from the hole H towards the active area AA can be prevented or minimized.

Referring to FIG. 3, the first inorganic encapsulation layer 171 is disposed in the first non-active area NA1. The first inorganic encapsulation layer 171 can extend from the active area AA into the first non-active area NA1. At this time, the first inorganic encapsulation layer 171 can cover top surfaces and side surfaces of the plurality of first dams DM1, and can cover top surfaces and side surfaces of the plurality of patterns PT in the first non-active area NA1.

A first organic encapsulation layer 172a and a second organic encapsulation layer 172b are disposed on the first inorganic encapsulation layer 171 in the first non-active area NA1.

The first organic encapsulation layer 172a is disposed in the active area AA and a part of the first non-active area NA1 extending from the active area AA. For example, an end of the first organic encapsulation layer 171a is disposed on the bank 154 in the first non-active area NA1. Therefore, a top surface of the first inorganic encapsulation layer 171 disposed on the bank 154 at an area outside of the first organic encapsulation layer 172a is exposed.

The second organic encapsulation layer 172b is disposed at the area outside of the first organic encapsulation layer 172a in the first non-active area NA1. The second organic encapsulation layer 172b can be disposed to be spaced apart from the first organic encapsulation layer 172a (e.g., the second organic encapsulation layer 172b is disconnected from the first organic encapsulation layer 172a). For example, the second organic encapsulation layer 172b is disposed between the plurality of first dams DM1 and can also be disposed between ends of the first planarization layer 110, a second planarization layer 111, and the bank 154, and one of the plurality of first dams DM1 which is closest to the active area AA.

The top surface of the second organic encapsulation layer 172b disposed in the first non-active area NA1 can be disposed to be lower than top surfaces of the plurality of first dams DM1. Further, an end of the second organic encapsulation layer 172b facing away from the active area is inclined down to the substrate, as shown in FIG. 3 (e.g., the end of second organic encapsulation layer 172b is sloped or tapered in a direction towards the hole H). That is, the end of the second organic encapsulation layer 172b farthest from the active area is inclined down to the substrate. Thus, it can be sure that the second organic encapsulation layer 172b is disconnected and terminates in an area between the plurality of first dams DM1, before reaching the hole H.

The second organic encapsulation layer 172 can be disposed to be filled between the plurality of patterns PT. In the meantime, a plurality of sections of the second organic encapsulation layer 172b can be disposed to be spaced apart and disconnected from each other between the plurality of patterns PT. In the meantime, it is not limited thereto and the plurality of sections of the second organic encapsulation layer 172b can be connected to each other between the plurality of patterns PT.

The second inorganic encapsulation layer 173 can extend from the active area AA to the first non-active area NA1. At this time, the second inorganic encapsulation layer 173 can cover a top surface of the first inorganic encapsulation layer 171 exposed between the first organic encapsulation layer 172a and the second organic encapsulation layer 172b, in order to form a repeating sealing structure. For example, the first inorganic encapsulation layer 171 and the second inorganic encapsulation layer 173 can be in contact with each other on the bank 154 at the area outside of the end of the first organic encapsulation layer 172a. Therefore, the first inorganic encapsulation layer 171 and the second inorganic encapsulation layer 173 can seal the first organic encapsulation layer 172a and block moisture penetration.

Further, in an area adjacent to the hole H, the first inorganic encapsulation layer 171 and the second inorganic encapsulation layer 173 can be in contact with each other, thus, also sealing an edge of the hole H. In the meantime, the second inorganic encapsulation layer 173 can cover a top surface of the first inorganic encapsulation layer 171 which is exposed between the plurality of sections of the second organic encapsulation layer 172b. First, on the first dam DM1, the first inorganic encapsulation layer 171 can be in contact with the second inorganic encapsulation layer 173. Further, on the plurality of patterns PT, the first inorganic encapsulation layer 171 can be in contact with the second inorganic encapsulation layer 173. By doing this, the first inorganic encapsulation layer 171 and the second inorganic encapsulation layer 173 can repeated seal the second organic encapsulation layer 172b multiple times so that the organic encapsulation 172 is repeatedly disconnected and cut many times in the area between the active area AA and the hole H.

In the meantime, when the top surface of the second organic encapsulation layer 172b is disposed to be lower than top surfaces of the first planarization layer 110 and the second planarization layer 111, the second inorganic encapsulation layer 173 can be in contact with the first inorganic encapsulation layer 171 in an area overlapping a side surface of the first planarization layer 110, a side surface of the second planarization layer 111, and a side surface of the bank 154 disposed in the first non-active area NA1.

Further, when a top surface of the second organic encapsulation layer 172b is disposed to be lower than the top surfaces of the plurality of patterns PT, the second inorganic encapsulation layer 173 can be in contact with the first inorganic encapsulation layer 171 in an area overlapping side surfaces of the plurality of patterns PT disposed in the first non-active area NA1.

Hereinafter, a second non-active area NA2 of a display device according to an example embodiment of the present disclosure will be described with reference to FIG. 4.

FIG. 4 is a cross-sectional view taken along line IV-IV′ of FIG. 1 according to an embodiment of the present disclosure. FIG. 4 is a schematic cross-sectional view of a second non-active area NA2 disposed at an outer periphery of the active area AA.

Referring to FIG. 4, the second non-active area NA2 is disposed to enclose the active area AA. For example, the second non-active area NA2 can be a bezel area or an outer perimeter of the display panel.

A plurality of second dams DM2 are disposed in the second non-active area NA2. Each of the plurality of second dams DM2 can have a closed curve shape which encloses the active area AA. For example, the plurality of second dams DM2 can fully surround or encircle the active area AA in a plan view. The plurality of second dams DM2 can suppress overflowing of the organic encapsulation layer 172 into the second non-active area NA2. Although it is shown that there are two second dams DM2 in FIG. 4, the number of second dams is not limited thereto. For example, three or more second dams can be disposed in the second non-active area NA2.

Each of the plurality of second dams DM2 includes a first sub dam DM2a, a second sub dam DM2b, and a third sub dam DM2c. The first sub dam DM2a of the second dam DM2 is formed of the same material as the inorganic insulating layer disposed below the first planarization layer 110. The second sub dam DM2b can be formed of the same material as the first planarization layer 110 and the second planarization layer 111. The third sub dam DM2c can be formed of the same material as the bank 154. However, a material of the insulating layer of the second dam DM2 and the number of layers are not limited thereto.

The first inorganic encapsulation layer 171 can extend from the active area AA to the second non-active area NA2. At this time, the first inorganic encapsulation layer 171 can cover top surfaces and side surfaces of the plurality of second dams DM2 in the second non-active area NA2.

Referring to FIG. 4, the first organic encapsulation layer 172a and the third organic encapsulation layer 172c are disposed in the second non-active area NA2.

The first organic encapsulation layer 172a is disposed in the active area AA and a part of the second non-active area NA2 extending from the active area AA. For example, the first organic encapsulation layer 172a is disposed between the active area AA and a second dam DM2 which is closest to the active area AA, among the plurality of second dams DM2.

The third organic encapsulation layer 172c is disposed at the area outside of the first organic encapsulation layer 172a in the second non-active area NA2. The third organic encapsulation layer 172c is disposed to be spaced apart and disconnected from the first organic encapsulation layer 172a in the second non-active area NA2 so that the organic encapsulation layer 172 is disconnected in the second non-active area NA2. In other words, the organic encapsulation layer 172 can be cut and disconnected by one or more of the plurality of second dams DM2.

The top surface of the third organic encapsulation layer 172c disposed in the second non-active area NA2 can be disposed to be lower than top surfaces of the plurality of second dams DM2. Accordingly, the third organic encapsulation layer 172c is not disposed on the top surfaces of the plurality of second dams DM2. A plurality of sections of the third organic encapsulation layer 172c can be disposed to be spaced apart and disconnected from each other between the plurality of second dams DM2. Further, an end of the third organic encapsulation layer 172c facing away from the active area is inclined down to the substrate, as shown in FIG. 4. That is, the end of the third organic encapsulation layer 172c farthest from the active area is inclined down to the substrate. For example, the end of the third organic encapsulation layer 172c facing the outer edge of bezel can be sloped or tapered. Thus, it can ensure that the third organic encapsulation layer 172c is fully disconnected between the plurality of second dams DM2. Since the second organic encapsulation layer 172b and the third organic encapsulation layer 172c are disposed in different areas, the ends of the first part and the second part are inclined with different inclinations. Particularly, the inclined end of the second organic encapsulation layer has a smaller inclination than that of inclined end of the third organic encapsulation layer to achieve a suitable protection in the first and second non-active areas.

The second inorganic encapsulation layer 173 can extend from the active area AA to the second non-active area NA2. At this time, the second inorganic encapsulation layer 173 can cover a top surface of the first inorganic encapsulation layer 171 exposed between the first organic encapsulation layer 172a and the third organic encapsulation layer 172c. For example, on the plurality of second dams DM2, the first inorganic encapsulation layer 171 can be in contact with the second inorganic encapsulation layer 173. Therefore, the plurality of sections of the third organic encapsulation layer 172c disposed between the plurality of second dams DM2 in the second non-active area NA2 can be repeatedly sealed by the first inorganic encapsulation layer 171 and the second inorganic encapsulation layer 173.

Although it is described that the organic encapsulation layer 172 includes the first organic encapsulation layer 172a, the second organic encapsulation layer 172b and the third organic encapsulation layer 172c, the three organic encapsulation layers can be renamed. For example, the second organic encapsulation layer 172b is disposed in the first non-active area NA1 and can be named as a first part, the third organic encapsulation layer 172c is disposed in the second non-active area NA2 and can be named as a second part, and the first organic encapsulation layer 172a can be named as a third part.

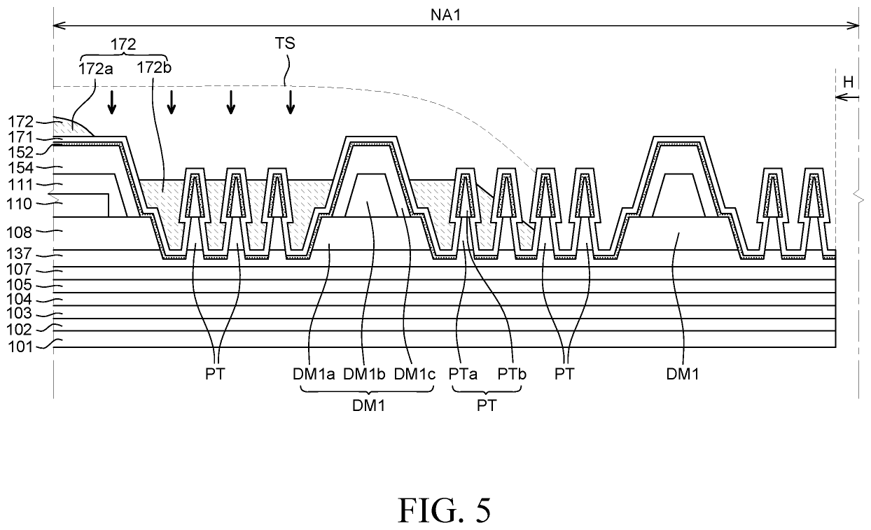

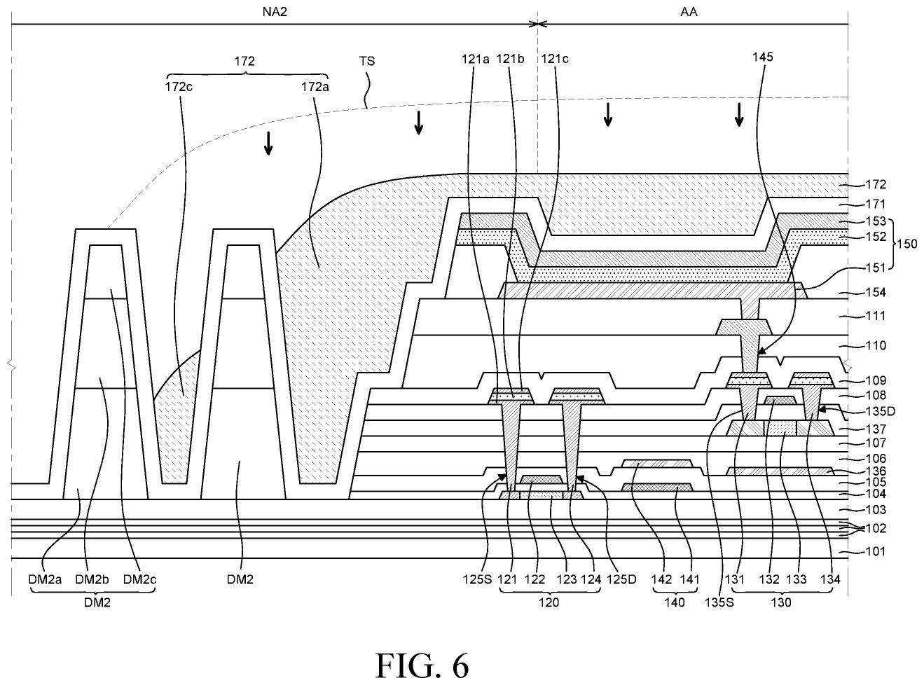

Hereinafter, a manufacturing process of a display device 100 according to an example embodiment of the present disclosure will be described with reference to FIGS. 5 and 6.

FIGS. 5 and 6 are cross-sectional views for explaining a manufacturing process of a display device according to an example embodiment of the present disclosure. FIGS. 5 and 6 are cross-sectional views for explaining an ashing process of a display device 100 according to an example embodiment of the present disclosure. FIG. 5 is a cross-sectional view for explaining an ashing process performed before forming the second inorganic encapsulation layer 173 in the display device 100 illustrated in FIG. 3. FIG. 6 is a cross-sectional view for explaining an ashing process performed before forming the second inorganic encapsulation layer 173 in the display device 100 illustrated in FIG. 4.

In the display device 100 according to the example embodiment of the present disclosure, an ashing process can be performed on the organic encapsulation layer 172. A thickness of the organic encapsulation layer 172 can be reduced by means of the ashing process. The reference numeral TS denotes a prior top surface of the organic encapsulation layer 172 before the ashing process and is illustrated with a dotted line.

First, referring to FIG. 5, the organic encapsulation layer 172 is disposed on the first inorganic encapsulation layer 171. At this time, the organic encapsulation layer 172 before the ashing process can cover a first dam DM1 which is closest to the active area AA, among the plurality of first dams DM1. Therefore, as illustrated in FIG. 5, the top surface of the organic encapsulation layer 172 can be disposed on the first dam DM1 which is closest to the active area AA, among the plurality of first dams DM1.

Thereafter, when the ashing process is performed, the thickness of the organic encapsulation layer 172 is reduced in an arrow direction illustrated in FIG. 5. A thickness of the entire organic encapsulation layer 172 can be reduced by the ashing process. Accordingly, as illustrated in FIG. 3, the organic encapsulation layer 172 can be formed.

Next, referring to FIG. 6, the organic encapsulation layer 172 is disposed on the first inorganic encapsulation layer 171. At this time, the organic encapsulation layer 172 before the ashing process can cover a second dam DM2 which is closest to the active area AA, among the plurality of second dams DM2. Therefore, as illustrated in FIG. 6, the top surface of the organic encapsulation layer 172 can be disposed on the second dam DM2 which is closest to the active area AA, among the plurality of second dams DM2.

Thereafter, when the ashing process is performed, the thickness of the organic encapsulation layer 172 is reduced in an arrow direction illustrated in FIG. 6. A thickness of the entire organic encapsulation layer 172 can be reduced by the ashing process. Accordingly, as illustrated in FIG. 4, the organic encapsulation layer 172 can be formed.

The organic encapsulation layer is formed of an organic material having the good flowability to be applied to flow wider than a design value. Therefore, when the organic encapsulation layer is excessively applied, moisture and oxygen move or wick along the organic encapsulation layer to cause a defect of the transistor or the light emitting diode in the display device and deteriorate a quality of the display device. Specifically, in the display device in which a hole is disposed, moisture and oxygen can additionally permeate through the organic encapsulation layer disposed in an area in which the hole is disposed. Therefore, when the moisture or oxygen permeates through the area in which the hole is disposed, the reliability can be deteriorated in the display device.

Accordingly, in the display device 100 according to the example embodiment of the present disclosure, the ashing process is performed on the organic encapsulation layer 172 to suppress the permeation problem through the area with the hole H. A thickness of the organic encapsulation layer 172 can be reduced by the ashing process. At this time, the organic encapsulation layer 172 which is disposed with a relatively small thickness at an end of the first non-active area NA1 can be removed. Therefore, the organic encapsulation layer 172 can include a second organic encapsulation layer 172b spaced apart and disconnected from the first organic encapsulation layer 172a extending from the active area AA. Further, the second organic encapsulation layer 172b can be disposed to be separated or cut into a plurality of sections between the plurality of first dams DM1 in the first non-active area NA1. By doing this, the first inorganic encapsulation layer 171 and the second inorganic encapsulation layer 173 can repeatedly seal the second organic encapsulation layer 172b. Therefore, in the display device 100 according to the example embodiment of the present disclosure, a movement path of moisture and oxygen through the organic encapsulation layer 172 in an area adjacent to the hole H disposed in the first non-active area NA1 can be effectively blocked.

Further, in the display device 100 according to the example embodiment of the present disclosure, the ashing process is performed on the entire area of the substrate 101 so that a thickness of the entire organic encapsulation layer 172 disposed on the substrate 101 can be reduced. Therefore, the organic encapsulation layer 172 which is disposed with a relatively small thickness at an end of the second non-active area NA2 can be removed. Therefore, the organic encapsulation layer 172 can include a third organic encapsulation layer 172c spaced apart and disconnected from the first organic encapsulation layer 172a by the second dam DM2 which is closest to the active area AA. Accordingly, the third organic encapsulation layer 172c is sealed by the first inorganic encapsulation layer 171 and the second inorganic encapsulation layer 173 between the plurality of second dams DM2 to block the moisture or impurity permeating into the active area AA, in the second non-active area NA2. Accordingly, the display device 100 according to the example embodiment of the present disclosure improves durability and reliability of the display device 100 and can improve image quality and extend the lifespan of the device.

Further, in the display device 100 according to the example embodiment of the present disclosure, the ashing process is performed on the organic encapsulation layer 172 so that even though the organic encapsulation layer 172 overflows, the organic encapsulation layer 172 disposed in a position adjacent to the hole H can be removed. Accordingly, in the display device 100 according to the example embodiment of the present disclosure, a greater process margin is ensured in the process of forming the organic encapsulation layer 172 to reduce the number of defects and improve a manufacturing yield of the display device 100.

The example embodiments of the present disclosure can also be described as follows:

According to an aspect of the present disclosure, there is provided a display device. The display device includes a substrate including a first non-active area, an active area which encloses the first non-active area, and a second non-active area which encloses the active area, a light emitting diode which is disposed in the active area of the substrate; and an encapsulation layer which is disposed on the substrate to cover the light emitting diode and includes a first inorganic encapsulation layer, an organic encapsulation layer disposed on the first inorganic encapsulation layer, and a second inorganic encapsulation layer disposed on the organic encapsulation layer, in which the substrate includes a hole formed in the first non-active area, and the organic encapsulation layer is disposed to be disconnected between the active area and the hole.

The organic encapsulation layer can include a first organic encapsulation layer which is disposed in the active area and a part of the first non-active area extending from the active area; and a second organic encapsulation layer which is disposed in the first non-active area and is spaced apart from the first organic encapsulation layer.

The display device can further include a bank which is disposed on the substrate and defines an emission area and a non-emission area of the light emitting diode, and an end of the first organic encapsulation layer can be disposed on the bank in the first non-active area.

The first inorganic encapsulation layer can be in contact with the second inorganic encapsulation layer on the bank at the outside of the end of the first organic encapsulation layer.

The display device can further include a plurality of first dams which is disposed in the first non-active area to enclose the hole, in which the second organic encapsulation layer can be disposed between the bank and one of the plurality of first dams which is closest to the active area.

The second organic encapsulation layer can be disposed between the plurality of first dams.

A top surface of the second organic encapsulation layer can be disposed to be lower than top surfaces of the plurality of first dams.

The first inorganic encapsulation layer can be in contact with the second inorganic encapsulation layer on the plurality of first dams.

The display device can further include a plurality of patterns disposed between the bank and the one of the plurality of first dams which is closest to the active area and between the plurality of first dams to enclose the hole, in which the second organic encapsulation layer can be disposed to be filled between the plurality of patterns.

The second organic encapsulation layer can be disposed to be separated into a plurality of sections between the plurality of patterns.

The first inorganic encapsulation layer can be in contact with the second inorganic encapsulation layer on the plurality of patterns.

The display device can further include a plurality of second dams which is disposed in the second non-active area to enclose the active area, in which the organic encapsulation layer can further include a third organic encapsulation layer which is disposed between the plurality of second dams and is spaced apart from the first organic encapsulation layer.

The first inorganic encapsulation layer can be in contact with the second inorganic encapsulation layer on the plurality of second dams.

The display device can further include a camera disposed in a position corresponding to the hole.

Each of the plurality of patterns can include a first sub pattern and a second sub pattern, and a cross-sectional shape each of the first sub pattern and the second sub pattern can have a tapered trapezoidal shape, and a top surface of the first sub pattern can have a smaller width than that of a bottom surface of the second sub pattern.

Each of the plurality of first dams can be formed in a closed curve shape enclosing the outer periphery of the hole.

Each of the plurality of second dams can have a closed curve shape which encloses the active area.

Each of the plurality of patterns can be formed in a closed curve shape enclosing the outer periphery of the hole.

The light emitting diode can be composed of an anode electrode, an emission stack and a cathode electrode, in which the emission stack can be disposed to extend from the active area into the first non-active area.

The emission stack can be disposed above the plurality of patterns can be disconnected.

The emission stack disposed above and between the plurality of patterns can be disconnected.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a substrate including a first non-active area, an active area surrounding the first non-active area, and a second non-active area surrounding the active area;
a light emitting diode disposed in the active area of the substrate; and
an encapsulation layer disposed on the light emitting diode, the encapsulation layer including a first inorganic encapsulation layer, an organic encapsulation layer disposed on the first inorganic encapsulation layer, and a second inorganic encapsulation layer disposed on the organic encapsulation layer; and
a hole extending through the substrate in the first non-active area,
wherein the organic encapsulation layer is disconnected or terminates in an area located between the active area and the hole.

2. The display device according to claim 1, wherein the organic encapsulation layer includes:
a first organic encapsulation layer disposed in the active area and in a part of the first non-active area extending from the active area; and
a second organic encapsulation layer disposed in the first non-active area, the second organic encapsulation layer being spaced apart from the first organic encapsulation layer.

3. The display device according to claim 2, further comprising:
a bank disposed on the substrate, the bank defining an emission area and a non-emission area of the light emitting diode,
wherein an end of the first organic encapsulation layer is disposed on the bank in the first non-active area.

4. The display device according to claim 3, wherein the first inorganic encapsulation layer is in contact with the second inorganic encapsulation layer on the bank at an area outside of the end of the first organic encapsulation layer.

5. The display device according to claim 3, further comprising:
a plurality of first dams disposed in the first non-active area, the plurality of first dams surrounding the hole,
wherein the second organic encapsulation layer is disposed between the bank and one of the plurality of first dams which is closest to the active area.

6. The display device according to claim 5, wherein the second organic encapsulation layer is disposed between the plurality of first dams.

7. The display device according to claim 6, wherein a top surface of the second organic encapsulation layer is lower than top surfaces of the plurality of first dams.

8. The display device according to claim 6, wherein the first inorganic encapsulation layer is in contact with the second inorganic encapsulation layer in areas over the plurality of first dams.

9. The display device according to claim 6, further comprising:
a plurality of patterns disposed between the bank and the one of the plurality of first dams which is closest to the active area and between the plurality of first dams, the plurality of first dams surrounding the hole,
wherein the second organic encapsulation layer is at least partially filled between the plurality of patterns.

10. The display device according to claim 9, wherein the second organic encapsulation layer separated into a plurality of sections between the plurality of patterns, the plurality of sections of the second organic encapsulation layer being spaced apart and disconnected from each other.

11. The display device according to claim 9, wherein the first inorganic encapsulation layer is in contact with the second inorganic encapsulation layer in one or more areas over the plurality of patterns.

12. The display device according to claim 2, further comprising:
a plurality of second dams disposed in the second non-active area, the plurality of second dams surrounding the active area,
wherein the organic encapsulation layer further includes a third organic encapsulation layer disposed between the plurality of second dams, the third organic encapsulation being spaced apart and disconnected from the first organic encapsulation layer.

13. The display device according to claim 12, wherein the first inorganic encapsulation layer is in contact with the second inorganic encapsulation layer in one or more areas over the plurality of second dams.

14. The display device according to claim 1, further comprising:
a camera disposed in a position corresponding to the hole.

15. The display device according to claim 9, wherein each of the plurality of patterns includes a first sub pattern and a second sub pattern,
wherein a cross-sectional shape of each of the first sub pattern and the second sub pattern has a tapered trapezoidal shape or a triangular shape, and
wherein a top surface of the first sub pattern has a smaller width than a bottom surface of the second sub pattern.

16. The display device according to claim 5, wherein each of the plurality of first dams is formed in a closed curve shape enclosing an outer periphery of the hole.

17. The display device according to claim 12, wherein each of the plurality of second dams has a closed curve shape enclosing the active area.

18. The display device according to claim 9, wherein each of the plurality of patterns is formed in a closed curve shape enclosing an outer periphery of the hole.

19. The display device according to claim 9, wherein the light emitting diode includes an anode electrode, an emission stack and a cathode electrode, and
wherein the emission stack extends from the active area into the first non-active area.

20. The display device according to claim 19, wherein portions of the emission stack disposed on the plurality of first dams are disconnected from each other.

21. The display device according to claim 19, wherein portions of the emission stack disposed on the plurality of patterns are disconnected from each other.
